(19) United States
(12) Patent Application Publication
(10) Pub. No.: US 2024/0001789 A1
(43) Pub. Date: Jan. 4, 2024

(54) AN ASSEMBLY FOR AN ELECTRIC VEHICLE CHARGER

(71) Applicant: Tritium Holdings Pty Ltd, Murarrie (AU)

(72) Inventors: Bernard Brian WALSH, Brisbane (AU); David Andrew FINN, Brisbane (AU); James McFarlane KENNEDY, Brisbane (AU); Michael John WALTON, Brisbane (AU); Jordan Christopher PIERCE, Brisbane (AU); Calem Timothy WALSH, Brisbane (AU); Aaron Jarvis PALM, Brisbane (AU)

(21) Appl. No.: 18/037,208

(22) PCT Filed: Nov. 17, 2021
(86) PCT No.: PCT/AU2021/051365

§ 371 Date: May 16, 2023

(30) Foreign Application Priority Data
Nov. 17, 2020 (AU) 2020904237

(51) Int. Cl. B60L 53/302; B60L 53/31; H05K 7/20

(52) U.S. Cl. CPC B60L 53/302; B60L 53/31; H05K 7/20863

(57) ABSTRACT

An assembly for an electric vehicle charger. The assembly comprising an electric vehicle charger housing having a first side wall, a second side wall and a porous membrane providing gas communication between an interior and exterior of the housing. Arranged within the housing are one or more electronics modules, an output circuit, and a heat exchanger. The assembly also includes a first air channel located between the one or more electronics modules and the first side wall of the housing, the first air channel being in fluid communication with the output circuit and the heat exchanger, and a second air channel located between the one or more electronics modules and the second side wall of the housing, the second air channel being in fluid communication with the output circuit and the heat exchanger.

### TECHNICAL FIELD

The present invention relates to an assembly for an electric vehicle charger. In particular, the present invention relates to an assembly for an electric vehicle charger having optimised air flow and heat dissipation.

### BACKGROUND

Any references to methods, apparatus or documents of the prior art are not to be taken as constituting any evidence or admission that they formed, or form part of the common general knowledge.

An electric vehicle (EV) charger typically includes a number of delicate electronic components arranged with a housing.

These electronic components generate heat as a result of electrical power consumption, and require a cooling system to prevent the components from overheating and becoming damaged. Cooling systems can be active cooling systems, such as liquid cooling systems for example, or uncontrolled ambient airflow cooling systems.

A primary negative effect of uncontrolled ambient airflow inside EV chargers is the damaging build-up of heat. Even when liquid cooling systems are utilised, one quarter (25%) or more of the heat output from EV charger electronics may remain unmitigated. This heat, consequently, requires proper thermal management. Furthermore, with modular EV charger systems now being developed to supersede older non-modular designs, the containment of DC-DC and AC-DC electronics inside module boxes has necessitated more onerous and active air-cooling solutions.

Moreover, it is desirable that, in modular EV charging systems, the ordinary wear incurred by modules through normal use is evenly distributed between the modules contained in any given EV charging unit. As a module being exposed to a relatively greater proportion of unmitigated heat as compared to the other modules in a charging unit is likely to result in a distinctly shorter lifespan for that module, cooling (whether by liquid or air) should hence be evenly distributed between the modules inside of modular EV chargers.

Other modular EV charger designs have attempted to overcome this problem with ‘through airflow’, which is the use of filters and fans, usually mounted to the side of chargers, to blow air through entire charging units, including the inside or outside of module boxes. These ‘through airflow’ solutions are sometimes used in combination with liquid cooling heat management systems. However, this solution results in a non-sealed charging system which permits ingress of dust and fluids, which can damage the electronics and significantly reduce their useable life.

Some other non-modular EV chargers utilise a sealed charging system but did not attempt to provide explicit airflow paths through the electronics. Such a design which was found to be unsuitable for a modular charger due to the possibly of non-balanced air flow distribution between the electronics which led to overheating in some components that were unable to be cooled sufficiently.

Furthermore, other modular EV charger designs which utilise liquid-cooling incorporate the entry of the coolant into module boxes at the backplane together with the backplane's power and/or data connectors. The grouping of liquid cooling pipes, power and/or data connectors in a single location at one end of a module severely restricts the possibility of air freely passing by the module at that end (e.g., to other modules) and in or out through the module generally. One solution to the problem of an overly impeded air channel is to simply widen the air channel. However, widening air channels would also widen the overall design of the charger and, consequently, inhibit the prospect of a charger bearing a ‘slimline’ design. As useable space for EV chargers is often at a premium, a larger footprint for the EV charger is undesirable and quickly results in large amounts of space being lost if multiple EV chargers are located in a single location.

The ingress of moisture and dust into an electric vehicle charger impacts on the functioning of electronics. Dust increases the chance of electrical breakdown (arc-over) between circuits, whilst moisture can saturate and cement dust coatings or increase conductivity between circuits, leading to short-circuits. Thus, in electric vehicle chargers that are “open”, in that they utilize through air-flow for essential cooling, the lifespan of internal components is reduced. To increase the lifetime of the components in a “open” air cooled design it is normally required to add large filters to the airflow path. The filters stop most of the dust but require regular maintenance to stop them getting blocked over time. As described, in a closed system air cooling is achieved not by through air-flow but through a cooling loop generated by the placement of the modules, fans, and heat exchange.

However, some form of internal and external gas diffusion/exchange is necessary even in a closed system for several reasons. Firstly, certain gases are emitted by the internal components during the functioning of the charger. These gases can cause degradation of internal components and can lead to an unsafe build-up of pressure or even combustion. Secondly, expansion and retraction of gases as chargers heat and cool, due to their functioning or external temperature variations, may lead to a build-up of pressure. The constant pressure changes can degrade the seals or if there is a leak it will actively pump moisture into the charger, leading to early failures. Thirdly, moisture that enters the system during installation or upgrade can also remain trapped in a closed system, causing degradation of internal components.

Thus, it is desirable to provide an assembly for an electric vehicle charger which overcomes or ameliorates the problems described above.

### SUMMARY OF INVENTION

In an aspect, the invention provides an assembly for an electric vehicle charger, the assembly comprising:
an electric vehicle charger housing having a first side wall, a second side wall and a porous membrane providing gas communication between an interior and exterior of the housing, and arranged within the housing:
   an electronics module;
   an output circuit; and
   a heat exchanger;
a first air channel located between the electronics module and the first side wall of the housing, the first air channel being in fluid communication with the output circuit and the heat exchanger; and
a second air channel located between the electronics module and the second side wall of the housing, the second air channel being in fluid communication with the output circuit and the heat exchanger.

Preferably, the assembly comprises a plurality of electronics modules.

In another aspect, the invention provides electric vehicle charger system, the system comprising:
an electric vehicle charger housing having a first side wall, a second side wall and a porous membrane providing gas communication between an interior and exterior of the housing, and arranged within the housing:
   one or more electronics modules;
   an output circuit; and
   a heat exchanger;
a first air channel located between the one or more electronics modules and the first side wall of the housing, the first air channel being in fluid communication with the output circuit and the heat exchanger; and
a second air channel located between the one or more electronics modules and the second side wall of the housing, the second air channel being in fluid communication with the output circuit and the heat exchanger.

Preferably, heated air is moved along the first air channel away from the output circuit toward the heat exchanger. That is, the first air channel is configured to move heated air therealong away from the output circuit toward the heat exchanger.

Preferably, cooled air is moved along the second air channel away from the heat exchanger toward the output circuit. That is, the second air channel is configured to move cooled air therealong away from the heat exchanger toward the output circuit.

Preferably, the first side wall of the housing is directly opposed to the second side wall of the housing.

Preferably, the first air channel is substantially parallel to the second air channel.

Preferably, at least one of the one or more electronics modules comprises a first opening on a first side of the electronics module and a second opening on a second side of the electronics module to allow cooled air to enter through the second opening from the second air channel and cool an interior of the electronics module and exit through the first opening into the first air channel. Preferably, the interior of the electronics module is in fluid communication with the first air channel and the second air channel. Preferably, a passage extends between the first opening on the first side of the electronics module and the second opening on the second side of the electronics module. Preferably, the passage connects the first air channel to the second air channel. Preferably, the first opening connects the interior of the electronics module to the first air channel and the second opening connects the interior of the electronics module to the second air channel.

Preferably, the one or more electronics modules comprise an inlet fan located at or adjacent the second opening to draw air from the second air channel into the electronics module.

Preferably, the one or more electronics modules comprise an outlet fan located at or adjacent the first opening to draw air from the interior of the electronics module into the first air channel.

Preferably, additionally arranged within the housing is a manifold connected to one or more of the one or more electronics modules. Preferably, the manifold is configured to deliver coolant to the connected electronics modules. Preferably, the manifold is located between the one or more electronics modules and the first side wall of the housing.

Preferably, the heat exchanger is located within the manifold.

Preferably, the heat exchanger comprises a radiator and a fan.

Preferably, the assembly further comprises second heat exchanger external to the housing. Preferably, the second heat exchanger is connected to the heat exchanger. Preferably, the second heat exchanger is in fluid communication with the heat exchanger. Preferably, the second heat exchanger comprises a radiator.

Preferably, additionally arranged within the housing is a backplane located between the one or more electronics modules and the second side wall of the housing.

Preferably, the heat exchanger is located at a first end of the housing between the first side wall and the second side wall.

Preferably, the output circuit is located at a second end of the housing between the first side wall and the second side wall.

Preferably, the porous membrane comprises a plastic porous membrane. Preferably, the porous membrane is gas permeable and/or liquid impermeable.

Preferably, the porous membrane has an ingress protection (IP) rating of greater than 66. Specifically, the porous membrane is adapted to prevent the ingress of moisture, water and dust but allow the communication of gas between the interior and exterior of the housing.

Preferably, the housing has an ingress protection (IP) rating of equal to or greater than 66. More preferably, the housing is adapted to prevent the ingress of moisture, water and dust.

Preferably, the housing comprises a rear wall connecting the first side wall and the second side wall. Preferably, the housing further comprises a top and a bottom at opposed ends of the first side wall and the second side wall. Preferably, the housing further comprises a door providing access to the interior of the housing. Preferably, the porous membrane is attached to the door. Preferably, the door includes an aperture, wherein the porous membrane is fitted over the aperture.

In another aspect, the invention provides a method of cooling an assembly for an electric vehicle charger, the method including the steps of:
providing an electric vehicle charger housing having a porous membrane providing gas communication between an interior and exterior of the housing, one or more electronics modules, an output circuit and a heat exchanger arranged therein;
generating airflow along a first air channel from the output circuit toward the heat exchanger, the first air channel being located between a first side wall of the housing and the one or more electronics module in the electric vehicle charger housing; and
generating airflow along a second air channel from the heat exchanger toward the output circuit, the second air channel being located between a second side wall of the housing and the one or more electronics module in the electric vehicle charger housing.

### BRIEF DESCRIPTION OF THE DRAWINGS

Preferred features, embodiments and variations of the invention may be discerned from the following Detailed Description which provides sufficient information for those skilled in the art to perform the invention. The Detailed Description is not to be regarded as limiting the scope of the preceding Summary of the Invention in any way. The Detailed Description will make reference to a number of drawings as follows:

FIG. 1 is a front view of an assembly for an electric vehicle charger in accordance with an embodiment of the present invention;

FIG. 2 illustrates the internal components as they would be arranged within the housing of the assembly for the electric vehicle charger;

FIG. 3 illustrates the internal components arranged within the housing;

FIG. 4 illustrates a section of the internal components of FIG. 2;

FIG. 5 illustrates a section of the housing and internal components of FIG. 3;

FIG. 6 illustrates another section of the internal components of FIG. 2;

FIG. 7 illustrates a section of the housing and backplane of the assembly;

FIG. 8 illustrates the housing from front and side views showing the air flow both internally and between the interior of the housing and the atmosphere; and

FIG. 9 is a flow diagram of a method of cooling an assembly for an electric vehicle charger.

### DETAILED DESCRIPTION OF PREFERRED EMBODIMENTS

Gas communication as used herein refers to the communication of a gas between two volumes, wherein a gas is substantially absent of liquid. However, it will be appreciated that minute or small quantities of liquid (e.g. liquid in air, such as water vapour) may be present in the gas.

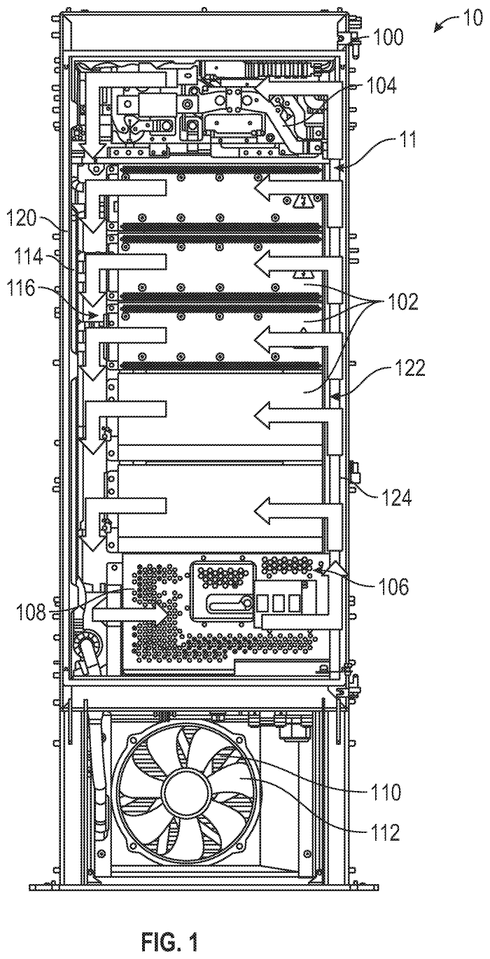

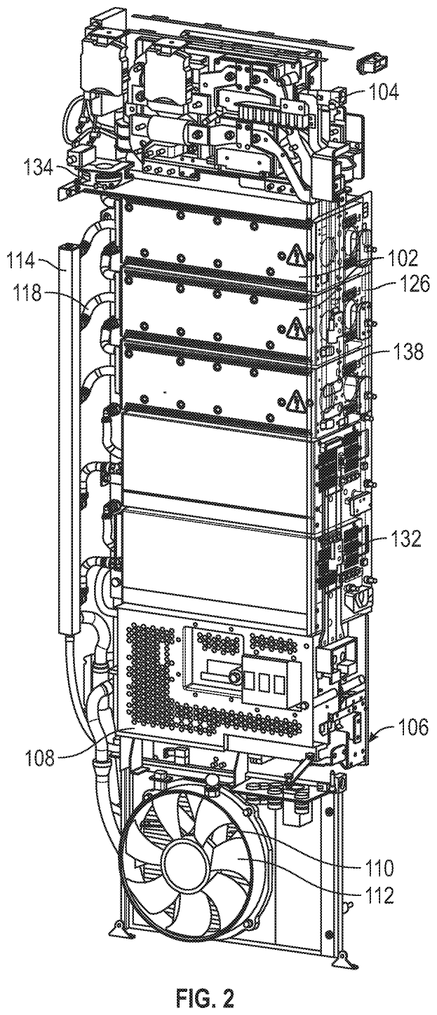

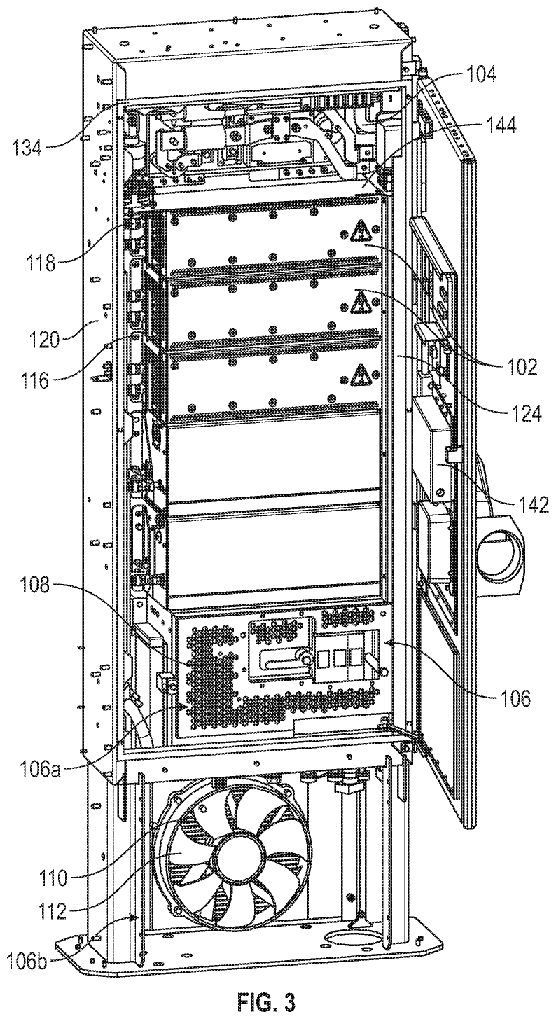

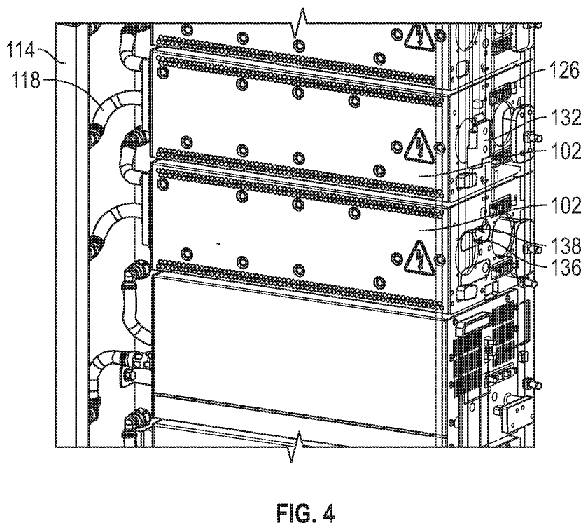

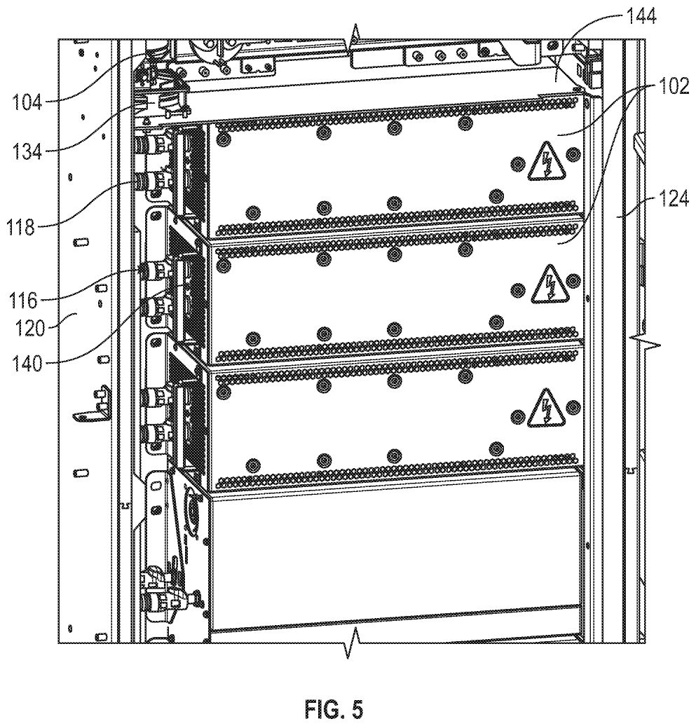

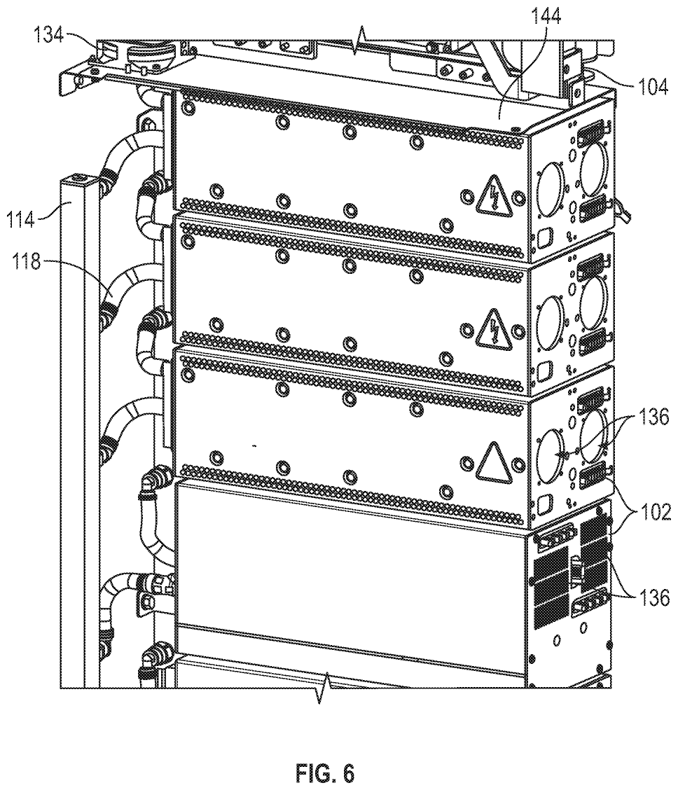

FIGS. 1 to 8 illustrate an assembly for an electric vehicle charger having optimised air flow and heat dissipation in the form of an electric vehicle charger assembly 10.

The electric vehicle (EV) charger assembly 10 includes a continuous or circular air channel loop 11 (also referred to as an air circuit) which circulates through an IP66 (ingress protection) rated housing 100 which houses a number of internal components for the operation of the electric vehicle charger assembly 10. The circular air channel loop 11 passes by and through the front and back of each of a plurality of electronics modules 102 which are all centrally located within the housing 100 of the EV charger assembly 10, through the output circuit 104 (which provides electric energy to an electric vehicle) located at the top end of the housing 100 of the EV charger assembly 10, and through the heat exchanger 106 located at the bottom end of the housing 100. The circular air channel loop 11 includes a first air channel 116 located on a first side of the housing 100 and a second air channel 122 located on an opposing, second side of the housing 100.

To allow the air to circulate through the circular air channel loop 11, the electronics modules 102 are all spaced apart from the sides of the housing 100.

In the present embodiment, the heat exchanger system 106 resides at the bottom end of the housing 100 and includes a first internal heat exchanger 106a and a second external heat exchanger 106b. The second external heat exchanger 106b is external to the housing 100 and is in fluid communication with the first internal heat exchanger 106a. The heat exchanger system 106 will be described in further detail below.

The heat exchanger system 106 is connected to both the air circuit 11 and a liquid cooling system including a liquid cooling manifold 114. The liquid cooling manifold 114 is connected to the plurality of electronics modules 102 and is configured to deliver a coolant to each of the connected electronics modules 102.

The second external heat exchanger 106b takes the form of an aluminium radiator 110 and fan 112 which forces air over the fins of the radiator 110 to cool the liquid within the radiator 110. The radiator 110 of the second external heat exchanger 106b receives the liquid of the liquid cooling system after it has circulated through the housing 100 and the electronics modules 102.

The first internal heat exchanger 106a takes the form of a heat exchange bracket 108 and a fan (not shown) which draws in and receives warm/hot air from the first air channel 116 of the air circuit 11. The first internal heat exchanger 106a also includes a radiator (not shown) which is in fluid communication with the radiator 110 of the second external heat exchanger 106a and receives the cooled liquid therefrom. As the fan of the first internal heat exchanger 106a forces the warm air over the fins of the radiator, the air drawn in from the first air channel 116 is cooled.

The first internal heat exchanger 106a also includes a circulation fan (not shown) for circulating the cooled air cooled by the cooled liquid flowing through the radiator of the first internal heat exchanger 106 back throughout the housing 100 along the second air channel 122. The first internal heat exchanger 106a and the second external heat exchanger 106b are devices suitably capable of heat transfer from one medium to another, and may take a number of forms other than or in addition to that described above. For example, the heat exchangers may include a radiator, heat sink and/or an air conditioning device.

Advantageously, the described arrangement of the heat exchanger system allows for a more compact EV charger design as the heat exchanger system uses the liquid cooling system to also cool the air flowing through the air channels.

Within the housing 100 is a first air channel 116 on a first side (e.g. the left side) of the housing 100 of the electric vehicle charger assembly 10.

The first air channel 116 is located between a first side wall 120 of the housing 100 and the electronics modules 102, and allows hot air to travel from the output circuit 104 at the top end of the housing 100 to the heat exchanger 106 located at the bottom end of the housing 100 where it is cooled by the heat exchanger 106 as described above. To assist with movement of the air from the output circuit 104 along the first air channel 116, the output circuit 104, in some embodiments, includes a fan 134.

Sufficient clearance for the first air channel 116 on the left side of the housing 100 is provided by positioning a significant portion of the liquid cooling pipes 118 within the manifold 114 between the first side wall 120 and the electronics modules 102. Arranging the liquid cooling pipes 118 and the manifold 114 in this manner allows free air flow along and through the first air channel 116 impeded only by two horizontally positioned pipes (one inlet pipe and one outlet pipe) per electronics module 102 extending from the manifold 114 through the first air channel 116 and into each electronics module 102.

Further to the first air channel 116, there is provided a second air channel 122 on a second side (e.g. the left side) within the housing 100 of the electric vehicle charger assembly 10.

The second air channel 122 is located between a second side wall 124 of the housing 100 (opposite the first side wall 120) and the electronics modules 102, and is intended to allow cooled air (relative to the hot air which travels along the first air channel 116) to travel from the heat exchanger 106 at the bottom end of the housing 100, passed, through and over the electronics module 102 to the output circuit 104 at the top end of the housing 100.

To assist with movement of the air from the heat exchanger 106 along the second air channel 122, the heat exchanger 106, in some embodiments, includes a fan (not shown).

Clearance for the second air channel 122 on the right side of the housing 100 is provided by positioning the single piece module-connecting backplane 126 a distance away from the second side wall 124 (e.g. the right side wall) of the housing 100. The distance between the backplane 126 and the second side wall 124 is preferably greater than 30 mm but the larger the distance the less impedance of the air flow.

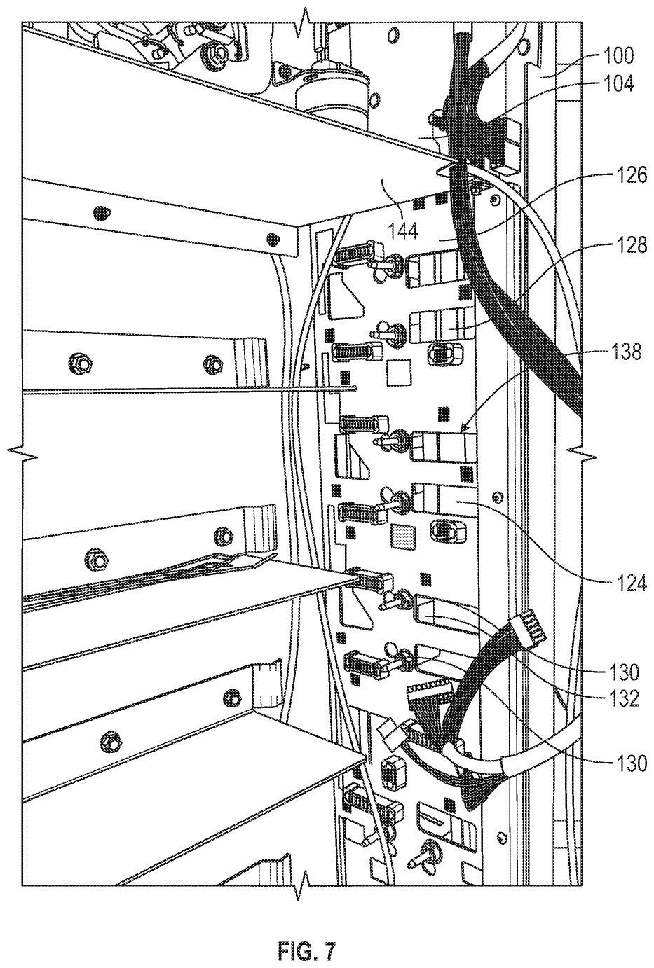

The second air channel 122 is impeded only by busbars 128 (see FIG. 7) connected to the backplane 126, mounting pins 130 for each electronics module 102 extending from the second side wall 124 of the housing 100 through the backplane 126, and aluminium spacers 132 between each mounting pin 130.

The separation of the backplane 126 on one side of the electronics modules 102, and the entry of the liquid cooling pipes 118 and manifold 114 on the other side of the electronics modules 102, reduces the possibility of airflow being impeded in either the first air channel 116 or the second air channel 122, thus enabling a slimmer EV charger design.

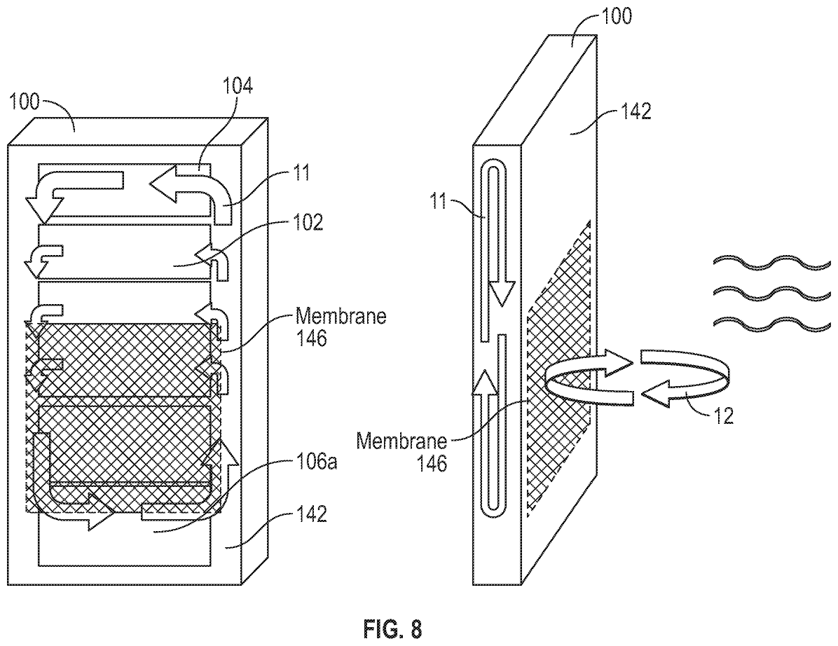

The charger door 142 also contains a porous membrane 146 (see FIG. 8) providing gas exchange between the interior and exterior of the housing 100.

In some embodiments, the charger door 142 includes an aperture (not shown) formed therein, wherein the porous membrane 146 is fitted over or across the aperture the aperture to facilitate gas communication between the interior and exterior of the housing 100.

The porous membrane 146 may take the form of a porous plastic membrane (commercially known as Porex), for example.

The porous membrane 146 permits a slow rate of gas diffusion from the housing to assist with cooling and ameliorating many or all of the issues that plague existing EV chargers with regard to internal gas and moisture build up. Furthermore, the membrane is highly ingress resistant and allows the housing to maintain the ingress protection (preferably IP66) of a sealed system to prevent unwanted fluid and dust ingress to the housing.

Although the porous membrane 146 is described in the present embodiment as being attached to the door, it should be appreciated that the porous membrane 146 can be located anywhere on the housing 100.

As mentioned above, the porous membrane 146 prevents the ingress of moisture and dust into the housing 100, while facilitating slow gas exchange between the interior of the housing 100 and the external environment the housing 100 is located in (indicated by loop 12 in FIG. 8). Advantageously, this provides a mechanism for equalising the internal pressure of the housing 100 with the ambient pressure of the atmosphere, and the chemical composition of the air of the interior of the housing 100 with the ambient air.

The porous membrane 146, which is preferably hydrophobic to block the ingress of water to the housing 100, also provides a release of water vapor via gas communication from the interior of the housing 100 to the exterior of the housing 100 thereby providing a mechanism for reducing the moisture content of the air within the housing 100.

In one embodiment, the porous membrane 146 is gas permeable. In another the porous membrane 146 is both gas permeable and liquid impermeable.

Unlike a cooling loop that cools components over several minutes (typically whilst the charger is in use), the gas exchange loop continuously functions, and completes a “loop” over several hours. The cooling loop is fast, by comparison, while the gas exchange through the porous membrane is slow. Advantageously, due to the slow pace of gas exchange loop, the cooling loop functions uninterrupted as the flow of internal air remains reasonably constant and is largely undisturbed. The combination of the cooling loop and the gas exchange allows the charging system to function safely and effectively.

It should be appreciated that the active water cooling system, which comparatively rapidly cools the housing, combined with the passive porous membrane allows the housing to effectively remain sealed against the ingress of water and dust (preferably at an IP rating of 66) while still allowing exchange of air and unwanted gas between the interior of the housing and the exterior of the housing.

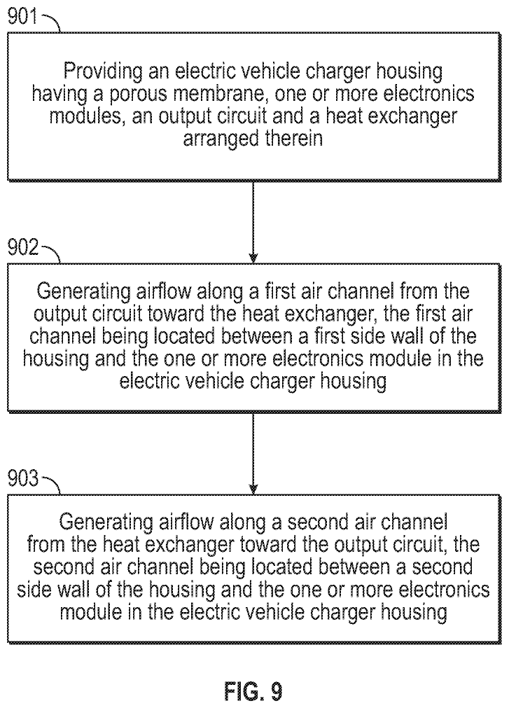

In use, an electric vehicle charger housing 100 is provided having one or more electronics modules 102, an output circuit 104 and a heat exchanger 106 arranged therein, as shown in box 901 of FIG. 9.

Broadly, circular air flows through the housing 100, which is indicated by the arrows in FIG. 1, and is regulated by one or more fans at both the top and bottom ends of the air circuit 11.

At the bottom end of the air circuit 11, there are one or more fans (not shown) in the heat exchanger 106 which draw in the hotter air from the first air channel 116 (the left air channel) to be cooled by the heat exchanger 106. Following the air-cooling process, the heat exchanger 106, as described above, blows the cooler air into the second air channel 122 (the right air channel).

This generates airflow along the first air channel 116 from the output circuit 104 toward the heat exchanger 106 as per box 902.

At the top end of the air circuit 11, there is at least one fan 134 in the output circuit 104 which draw cooler air from the second air channel 122 (the right air channel) and, following the cooling of the output circuit 104, blow hotter air into the first air channel 116 (the left air channel).

This generates airflow along the second air channel 122 from the heat exchanger 106 toward the output circuit 104 as per box 903.

Each electronics module 102 contains one or more fans (not shown) which draw in cooler air from the second air channel 122 through the inflow holes 136 in the side of the electronics modules 102 which are placed against holes 138 in the backplane 126. The holes 138 are aligned with the inflow holes 136 to allow air to flow from the second air channel 122 into the interior of the electronics module 102. Following the cooling of the electronics module 102, the hotter air is blown out into the first air channel 116 from an outflow hole 140 on the opposite end of the electronics module 102. In some embodiments, a second fan may be placed near or adjacent the outflow hole 130 to assist with removing the hotter air from the interior of the electronics module 102.

The optimised flow of air through the first air channel 116 and the second air channel 122 is also achieved through the blocking of alternative air travel paths.

During the operation described above, the porous membrane 146 prevents the ingress of moisture and dust while allowing the exchange of gas between the interior and exterior of housing 100 to assist with cooling and prevent unwanted internal moisture and gas build up which can be deleterious to the overall functionality and longevity of the charger.

Several components in the EV charger assembly 10 contribute to the blocking of air flow. These include the interior wall of the housing and the interior side of the charger door 142 which significantly prevent air from leaving the air circuit 11. The casing of all the electronics modules 102, the backplane 126, the mounting plate (not shown) for the heat exchanger 106, which prevents air from bypassing the heat exchanger 106, and the baffle plate 144 for the output circuit 104, which prevents air from bypassing the output circuit 104, also contribute to channeling the air through the first air channel 116 and second air channel 122 as desired.

When an electronics module is not installed in the housing 100, a ‘blocker plate’ can be secured in place of a module at the backplane 126 to block air flow along the second air channel 122 in the right hand side of the housing 100. However, the blocker plate does not need to block air flow along the first air channel 116 for flow to be maintained along that channel.

In some further embodiments, the arrangement of the housing can be vertically mirrored, whereby cooler air travels up the left channel and the hotter air travels down the right channel.

In some alternative embodiments, the location of the heat exchanger and the output circuit could be reversed such that the heat exchanger is located at the top of the housing and the output circuit is located at the bottom of the housing. In such embodiments, where the heat exchanger is positioned at the top of the air circuit, the one or more fans located in the heat exchanger would not be required to spin as quickly as when the heat exchanger is located at the bottom of the air circuit, since the former configuration results in less resistance to convection.

In some further embodiments, the heat exchanger could be integrated into the manifolds which house a significant portion of the liquid cooling pipes. Such an arrangement frees up a significant amount of space within the housing currently occupied by the heat exchanger and permits even greater packing density of the internal components of the EV charger assembly.

Embodiments of the invention, moreover, enable a more compact EV charger design as the same heat exchanger for the liquid cooling system is used to cool the air flowing through the air channels. Thus, two sealed cooling loops, one of liquid and the other of air, are provided through the same heat exchange, with the result being that separate heat exchanges for each cooling loop are unnecessary.

In compliance with the statute, the invention has been described in language more or less specific to structural or methodical features. The term “comprises” and its variations, such as “comprising” and “comprised of” is used throughout in an inclusive sense and not to the exclusion of any additional features.

It is to be understood that the invention is not limited to specific features shown or described since the means herein described comprises preferred forms of putting the invention into effect.

The invention is, therefore, claimed in any of its forms or modifications within the proper scope of the appended claims appropriately interpreted by those skilled in the art.

1. An assembly for an electric vehicle charger, the assembly comprising:
an electric vehicle charger housing having a first side wall, a second side wall and a porous membrane providing gas communication between an interior and exterior of the housing, and arranged within the housing:
an electronics module;
an output circuit; and
a heat exchanger;
a first air channel located between the electronics module and the first side wall of the housing, the first air channel being in fluid communication with the output circuit and the heat exchanger; and
a second air channel located between the electronics module and the second side wall of the housing, the second air channel being in fluid communication with the output circuit and the heat exchanger.

2. An assembly as claimed in claim 1, wherein the first air channel is configured to move heated air therealong away from the output circuit toward the heat exchanger and the second air channel is configured to move cooled air therealong away from the heat exchanger toward the output circuit.

3. An assembly as claimed in claim 1, wherein the first side wall of the housing is directly opposed to the second side wall of the housing and the first air channel is substantially parallel to the second air channel.

4. An assembly as claimed in claim 1, wherein the electronics module comprises a first opening on a first side of the electronics module and a second opening on a second side of the electronics module to allow cooled air to enter through the second opening from the second air channel and cool an interior of the electronics module and exit through the first opening into the first air channel such that the interior of the electronics module is in fluid communication with the first air channel and the second air channel.

5. An assembly as claimed in claim 4, wherein a passage extends between the first opening on the first side of the electronics module and the second opening on the second side of the electronics module and wherein the passage connects the first air channel to the second air channel.

6. An assembly as claimed in claim 5, wherein the first opening connects the interior of the electronics module to the first air channel and the second opening connects the interior of the electronics module to the second air channel.

7. An assembly as claimed in claim 4, wherein the electronics module comprises an inlet fan located at or adjacent the second opening to draw air from the second air channel into the interior of the electronics module and the electronics module comprises an outlet fan located at or adjacent the first opening to draw air from the interior of the electronics module into the first air channel.

8. An assembly as claimed in claim 1, the assembly further comprising a manifold arranged within the housing, wherein the manifold is connected to the electronics module, and wherein the manifold is configured to deliver coolant to the connected electronics module and the manifold is located between the electronics module and the first side wall of the housing.

9. An assembly as claimed in claim 8, wherein the heat exchanger is located within the manifold.

10. An assembly as claimed in claim 1, wherein the heat exchanger comprises a radiator and a fan.

11. An assembly as claimed in claim 1, the assembly further comprising a second heat exchanger external to the housing and the second heat exchanger is connected to the heat exchanger and the second heat exchanger is in fluid communication with the heat exchanger.

12. An assembly as claimed in claim 11, wherein the second heat exchanger comprises a radiator.

13. An assembly as claimed in claim 1, wherein the heat exchanger is located at a first end of the housing between the first side wall and the second side wall.

14. An assembly as claimed in claim 1,
the assembly further comprising a backplane arranged within the housing, wherein the backplane is located between the electronics module and the second side wall of the housing;
the housing further comprising a rear wall connecting the first side wall and the second side wall, and a top and a bottom at opposed ends of the first side wall and the second side wall, and wherein the output circuit is located at a second end of the housing between the first side wall and the second side wall.

15. An assembly as claimed in claim 1, wherein the porous membrane comprises a plastic porous membrane.

16. An assembly as claimed in claim 1, wherein the porous membrane is gas permeable and/or liquid impermeable, wherein the porous membrane is adapted to prevent the ingress of moisture, water and dust but allow the communication of gas between the interior and exterior of the housing.

17. An assembly as claimed in claim 1, wherein the housing is adapted to prevent the ingress of moisture, water and dust.

18. An assembly as claimed in claim 1, wherein the housing further comprises a door providing access to the interior of the housing, wherein the porous membrane is attached to the door, and the door includes an aperture, wherein the porous membrane is fitted over the aperture.

19. An assembly as claimed in claim 1, wherein the assembly comprises a plurality of electronics modules.

20. A method of cooling an assembly for an electric vehicle charger, the method including the steps of:
providing an electric vehicle charger housing having a porous membrane providing gas communication between an interior and exterior of the housing, an electronics module, an output circuit and a heat exchanger arranged therein;
generating airflow along a first air channel from the output circuit toward the heat exchanger, the first air channel being located between a first side wall of the housing and the electronics module in the electric vehicle charger housing; and
generating airflow along a second air channel from the heat exchanger toward the output circuit, the second air channel being located between a second side wall of the housing and the electronics module in the electric vehicle charger housing.
